(19) United States
(12) Patent Application Publication
(10) Pub. No.: US 2023/0420459 A1
(43) Pub. Date: Dec. 28, 2023

(54) INTEGRATED CIRCUIT DEVICES INCLUDING METALLIC SOURCE/DRAIN REGIONS

(71) Applicant: Samsung Electronics Co., Ltd., Suwon-si (KR)

(72) Inventors: Byounghak Hong, Albany, NY (US); Sooyoung Park, Clifton Park, NY (US); Jaehong Lee, Albany, NY (US); Kang-ill Seo, Albany, NY (US); WookHyun Kwon, Hwaseong-si (KR)

(21) Appl. No.: 18/056,181

(22) Filed: Nov. 16, 2022

Related U.S. Application Data
(60) Provisional application No. 63/355,868, filed on Jun. 27, 2022.

(51) Int. Cl. H01L 27/092; H01L 27/06; H01L 21/768

(52) U.S. Cl. CPC H01L 27/0922; H01L 27/0688; H01L 21/768

(57) ABSTRACT

Integrated circuit devices and methods of forming the same are provided. The integrated circuit devices may include a substrate and a transistor stack on the substrate. The transistor stack comprises a first transistor and a second transistor stacked in a first direction. The first transistor comprises first and second source/drain regions and a first channel region between the first and second source/drain regions, and the first source/drain region comprises a first metal layer. The second transistor comprises third and fourth source/drain regions and a second channel region between the third and fourth source/drain regions, and the first and third source/drain regions overlap each other in the first direction. The transistor stack further comprises a metal interconnector contacting the third source/drain region and the first metal layer of the first source/drain region material.

### CROSS-REFERENCE TO RELATED APPLICATION

This application claims priority to U.S. Provisional Application Ser. No. 63/355,868 entitled METAL SOURCE/DRAIN STRUCTURE IN 3D STACKED FET THE SAME, filed in the USPTO on Jun. 27, 2022, the disclosure of which is hereby incorporated by reference herein in its entirety.

### BACKGROUND

The present disclosure generally relates to the field of integrated circuit devices and, more particularly, to integrated circuit devices including a metallic source/drain region.

Various structures of an integrated circuit device and methods of forming the same have been proposed to improve the performance and/or to increase the integration density of the device. For example, various structures of an integrated circuit device have been developed to reduce parasitic capacitance and/or contact resistance between conductive elements of the device so as to increase the operation speed thereof. Further, various structures of an integrated circuit device have been developed to simplify the middle-of-line (MOL) portion and/or the back-end-of-line (BEOL) portion of device fabrication so as to increase the integration density of the device.

### SUMMARY

An integrated circuit devices according to some embodiments may include a substrate and a transistor stack on the substrate. The transistor stack comprises a first transistor and a second transistor stacked in a first direction. The first transistor comprises first and second source/drain regions and a first channel region between the first and second source/drain regions, and the first source/drain region comprises a first metal layer. The second transistor comprises third and fourth source/drain regions and a second channel region between the third and fourth source/drain regions, and the first and third source/drain regions overlap each other in the first direction. The transistor stack further comprises a metal interconnector contacting the third source/drain region and the first metal layer of the first source/drain region material.

An integrated circuit devices according to some embodiments may include a substrate and an upper transistor on the substrate. The upper transistor comprises upper source/drain regions and an upper channel region between the upper source/drain regions. The integrated circuit devices may also include a lower transistor between the substrate and the upper transistor. The lower transistor comprises lower source/drain regions and a lower channel region between the lower source/drain regions, and one of the lower source/drain regions comprises a first metal layer. Further, the integrated circuit devices may include a lower contact that is in the substrate and comprises a second metal layer contacting the first metal layer of the one of the lower source/drain regions.

A method of forming an integrated circuit devices according to some embodiments may include forming a preliminary transistor stack on a substrate, the preliminary transistor stack comprising an upper channel region and a lower channel region that is between the substrate and the upper channel region, forming first and second lower source/drain regions that respectively contact opposing side surfaces of the lower channel region and comprise a first semiconductor material, forming first and second upper source/drain regions that respectively contact opposing side surfaces of the upper channel region and comprise a second semiconductor material, and replacing at least one of the first semiconductor material of the first lower source/drain region and the second semiconductor material of the first upper source/drain region with a metal layer.

### BRIEF DESCRIPTION OF THE DRAWINGS

FIGS. 1-8 respectively are cross-sectional views of integrated circuit devices according to some embodiments.

FIG. 9 is a flow chart of methods of forming an integrated circuit device according to some embodiments.

FIGS. 10 through 15 are cross-sectional views illustrating methods of forming an integrated circuit device according to some embodiments.

### DETAILED DESCRIPTION

According to some embodiments, an integrated circuit device may include a metallic source/drain region that contacts a metallic interconnector (e.g., a metallic contact plug) such that contact resistance between the metallic source/drain region and the metallic interconnector can be lower compared to the case where an integrated circuit device includes a semiconductor source/drain region. Further, an integrated circuit device may include a back side power distribution network (BSPDN) structure such that the MOL portion and/or the BEOL portion of device fabrication can be simplified.

Example embodiments will be described in greater detail with reference to the attached figures.

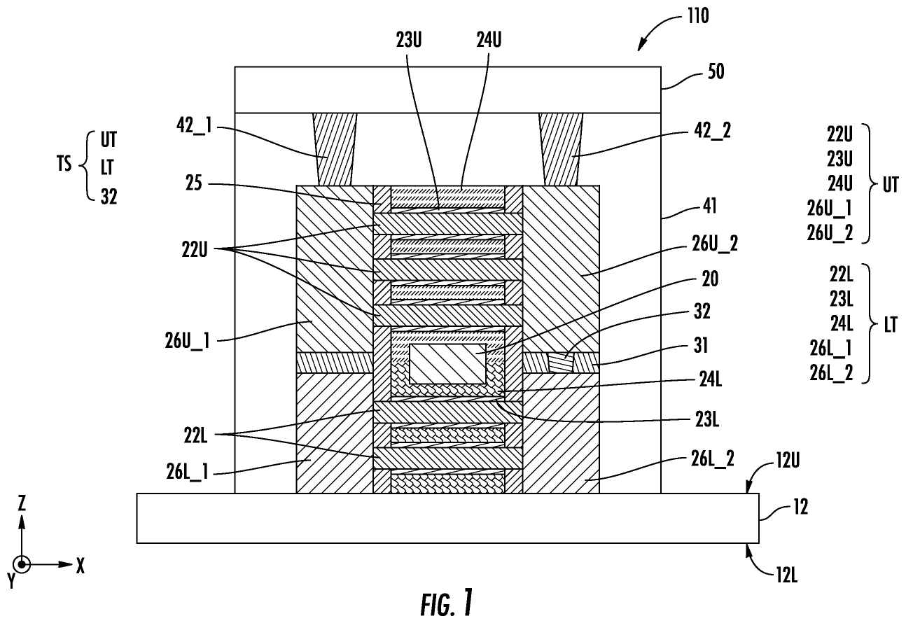

FIG. 1 is a cross-sectional view of a first integrated circuit device 110 according to some embodiments. The first integrated circuit device 110 may include a transistor stack TS on a substrate 12 that includes an upper surface 12U and a lower surface 12L. In some embodiments, the upper surface 12U of the substrate 12 may extend in a first direction X (also referred to as a first horizontal direction) and a second direction Y (also referred to as a second horizontal direction). In some embodiments, the first direction X may be perpendicular to the second direction Y. The upper surface 12U of the substrate 12 may be parallel to the lower surface 12L of the substrate 12.

The substrate 12 may include one or more semiconductor materials, for example, Si, Ge, SiGe, GaP, GaAs, SiC, SiGeC and/or InP. In some embodiments, the substrate 12 may be a bulk substrate (e.g., a bulk silicon substrate) or a semiconductor on insulator (SOI) substrate. For example, the substrate 12 may be a silicon wafer. A thickness of the substrate 12 in a third direction Z (also referred to as a vertical direction) may be in a range of 50 nm to 100 nm. In some embodiments, the third direction Z may be perpendicular to the first direction X.

The transistor stack TS may include an upper transistor UT and a lower transistor LT, and the upper transistor UT and the lower transistor LT may be stacked in the third direction Z, as illustrated in FIG. 1. The upper surface 12U of the substrate 12 may face the transistor stack TS. The lower transistor LT may be between the substrate 12 and the upper transistor UT. In some embodiments, the lower transistor LT and the upper transistor UT may have different conductivity types, and the transistor stack TS may be a complementary metal-oxide-semiconductor (CMOS) structure.

The lower transistor LT may include a lower channel region 22L that may be, for example, a semiconductor layer having a nano-scale thickness in the third direction Z. In some embodiments, the lower transistor LT may include multiple lower channel regions 22L stacked in the third direction Z, and the lower channel regions 22L may be spaced apart from each other in the third direction Z, as illustrated in FIG. 1.

The lower transistor LT may also include a lower gate structure that may include a lower gate insulator 23L and a lower gate electrode 24L. The lower channel region 22L may extend through the lower gate electrode 24L in the first direction X, and the lower gate insulator 23L may be provided between the lower gate electrode 24L and the lower channel region 22L for electrical isolation therebetween. The lower gate insulator 23L may contact the lower channel region 22L. In some embodiments, the lower gate electrode 24L may include a metallic layer and may additionally include work function layer(s) (e.g., a TiN layer, a TaN layer, a TiAl layer, a TiC layer, a TiAlC layer, a TiAlN layer and/or a WN layer). The work function layer(s) may be provided between the metallic layer and the lower gate insulator 23L. In some embodiments, the work function layer(s) may separate the metallic layer from the lower gate insulator 23L.

Further, the lower transistor LT may include first and second lower source/drain regions 26L_1 and 26L_2 that may be spaced apart from each other in the first direction X, and the lower gate structure may be provided between the first and second lower source/drain regions 26L_1 and 26L_2. Although FIG. 1 illustrates that the lower gate electrode 24L and the first and second lower source/drain regions 26L_1 and 26L_2 contact the upper surface 12U of the substrate 12, in some embodiments, a layer (e.g., an insulating layer) may be provided between the upper surface 12U of the substrate 12 and the lower gate electrode 24L and/or between the upper surface 12U of the substrate 12 and the first and second lower source/drain regions 26L_1 and 26L_2.

The upper transistor UT may include an upper channel region 22U that may be, for example, a semiconductor layer having a nano-scale thickness in the third direction Z. In some embodiments, the upper transistor UT may include multiple upper channel regions 22U stacked in the third direction Z, and the upper channel regions 22U may be spaced apart from each other in the third direction Z, as illustrated in FIG. 1.

The upper transistor UT may also include an upper gate structure that may include an upper gate insulator 23U and an upper gate electrode 24U. The upper channel region 22U may extend through the upper gate electrode 24U in the first direction X, and the upper gate insulator 23U may be provided between the upper gate electrode 24U and the upper channel region 22U for electrical isolation therebetween. The upper gate insulator 23U may contact the upper channel region 22U. In some embodiments, the upper gate electrode 24U may include a metallic layer and may additionally include work function layer(s) (e.g., a TiN layer, a TaN layer, a TiAl layer, a TiC layer, a TiAlC layer, a TiAlN layer and/or a WN layer). The work function layer(s) may be provided between the metallic layer and the upper gate insulator 23U. In some embodiments, the work function layer(s) may separate the metallic layer from the upper gate insulator 23U.

The first integrated circuit device 110 may also include an inter-gate insulator 20 that is provided between the lower gate electrode 24L and the upper gate electrode 24U. Although FIG. 1 illustrates that the lower gate electrode 24L includes portions contacting the upper gate electrode 24U, in some embodiments, the inter-gate insulator 20 may completely separate the lower gate electrode 24L from the upper gate electrode 24U, and the lower gate electrode 24L may not contact the upper gate electrode 24U. In other embodiments, the inter-gate insulator 20 may be omitted.

Further, the upper transistor UT may include first and second upper source/drain regions 26U_1 and 26U_2 that may be spaced apart from each other in the first direction X, and the upper gate structure may be provided between the first and second upper source/drain regions 26U_1 and 26U_2. In some embodiments, the first lower source/drain region 26L_1 and the first upper source/drain region 26U_1 may overlap each other in the third direction Z, and the second lower source/drain region 26L_2 and the second upper source/drain region 26U_2 may overlap each other in the third direction Z, as illustrated in FIG. 1. As used herein, “an element A overlapping an element B in a direction X” (or similar language) means that there is at least one line that extends in the direction X and intersects both the elements A and B.

Each of the lower channel region 22L and the upper channel region 22U may include semiconductor material(s) (e.g., Si, Ge, SiGe, GaP, GaAs, SiC, SiGeC and/or InP). In some embodiments, the lower channel region 22L and the upper channel region 22U may include the same material(s). In some embodiments, each of the lower channel region 22L and the upper channel region 22U may be a nanosheet that may have a thickness in a range of from 1 nm to 100 nm in the third direction Z or may be a nanowire that may have a circular cross-section with a diameter in a range of from 1 nm to 100 nm.

Each of the lower and upper gate insulators 23L and 23U may include a single layer or multiple layers (e.g., a silicon oxide layer and/or a high-k material layer). For example, the high-k material layer may include Al₂O₃, HfO₂, ZrO₂, HfZrO₄, TiO₂, Sc₂O₃ Y₂O₃, La₂O₃, Lu₂O₃, Nb₂O₅ and/or Ta₂O₅. In some embodiments, the lower and upper gate insulators 23L and 23U may include the same material(s). Each of the lower and upper gate electrodes 24L and 24U may include a single layer or multiple layers. In some embodiments, each of lower and upper gate electrodes 24L and 24U may include a metallic layer that includes, for example, tungsten (W), aluminum (Al), copper (Cu), molybdenum (Mo) and/or ruthenium (Ru). In some embodiments, the lower and upper gate electrodes 24L and 24U may include the same material(s).

Each of the first and second lower source/drain regions 26L_1 and 26L_2 may include a first metal layer that includes, for example, W, Al, Cu, Mo and/or Ru. In some embodiments, each of the first and second lower source/drain regions 26L_1 and 26L_2 may include a single metal layer (e.g., a tungsten layer). In some embodiments, the entirety of each of the first and second lower source/drain regions 26L_1 and 26L_2 may be the first metal layer.

Each of the first and second upper source/drain regions 26U_1 and 26U_2 may include a second metal layer that includes, for example, W, Al, Cu, Mo and/or Ru. In some embodiments, each of the first and second upper source/drain regions 26U_1 and 26U_2 may include a single metal layer (e.g., a tungsten layer). In some embodiments, the entirety of each of the first and second upper source/drain regions 26U_1 and 26U_2 may be the second metal layer. In some embodiments, the first and second upper source/drain regions 26U_1 and 26U_2 and the first and second upper source/drain regions 26U_1 and 26U_2 may include the same material(s).

The transistor stack TS may also include a metal interconnector 32 that electrically connects the second lower source/drain region 26L_2 to the second upper source/drain region 26U_2. In some embodiments, the metal interconnector 32 contacts both the second lower source/drain region 26L_2 and the second upper source/drain region 26U_2. The metal interconnector 32 may be provided in a first insulating layer 31 that is provided between the second lower source/drain region 26L_2 and the second upper source/drain region 26U_2. The metal interconnector 32 may extend through the first insulating layer 31 in the third direction Z. The first insulating layer 31 may also be provided between the first lower source/drain region 26L_1 and the first upper source/drain region 26U_1.

The transistor stack TS may also include an insulating spacer 25 (also referred to as a gate spacer or an inner gate spacer) that is provided between the upper gate electrode 24U and the first and second upper source/drain regions 26U_1 and 26U_2 for electrical isolation therebetween and/or is provided between the lower gate electrode 24L and the first and second lower source/drain regions 26L_1 and 26L_2 for electrical isolation therebetween. In some embodiments, opposing side surfaces (e.g., upper portions of the opposing side surfaces) of the insulating spacer 25 may respectively contact the upper gate electrode 24U and one of the first and second upper source/drain regions 26U_1 and 26U_2, and opposing side surfaces (e.g., lower portions of the opposing side surfaces) of the insulating spacer 25 may respectively contact the lower gate electrode 24L and one of the first and second lower source/drain regions 26L_1 and 26L_2, as illustrated in FIG. 1.

In some embodiments, the upper channel region 22U may extend through the insulating spacer 25 in the first direction X and may contact the one of the first and second upper source/drain regions 26U_1 and 26U_2. The lower channel region 22L may extend through the insulating spacer 25 in the first direction X and may contact the one of the first and second lower source/drain regions 26L_1 and 26L_2. The insulating spacer 25 may include, for example, silicon oxide, silicon oxynitride, silicon nitride, silicon carbonitride and/or a low-k material. For example, the low-k material may include fluorine-doped silicon oxide, organosilicate glass, carbon-doped oxide, porous silicon dioxide, porous organosilicate glass, spin-on organic polymeric dielectrics and/or spin-on silicon based polymeric dielectric.

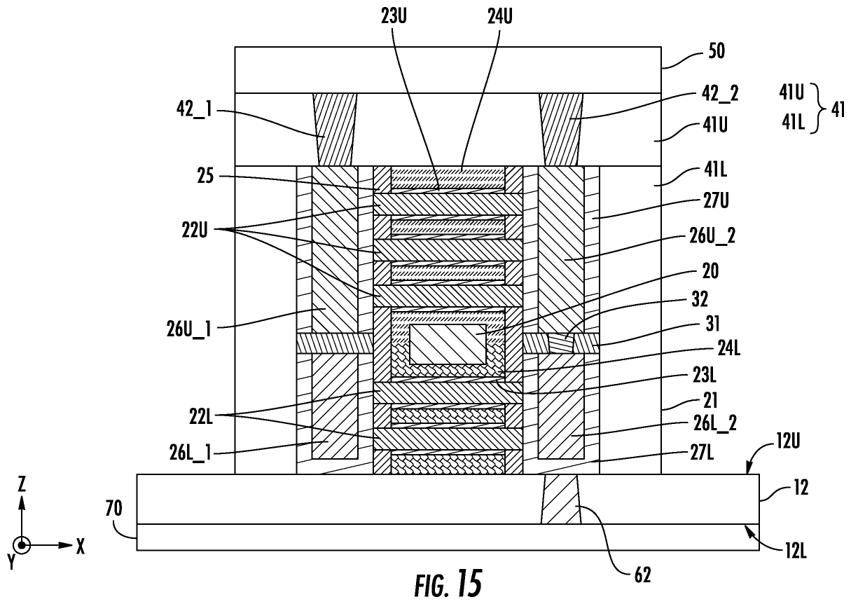

A second insulating layer 41 may be provided on the substrate 12, and the transistor stack TS may be provided in the second insulating layer 41. Although FIG. 1 illustrates that the second insulating layer 41 as a single layer, in some embodiments, the second insulating layer 41 may include multiple layers (e.g., a lower second insulating layer 41L and an upper second insulating layer 41U in FIG. 15).

First and second upper contacts 42_1 and 42_2 may be provided in the second insulating layer 41 on the transistor stack TS. The first upper contact 42_1 may electrically connect the first upper source/drain region 26U_1 to a conductive element (e.g., a conductive wire or a conductive via plug) of a BEOL structure 50 that is formed through the BEOL portion of device fabrication, and the second upper contact 42_2 may electrically connect the second upper source/drain region 26U_2 to a conductive element (e.g., a conductive wire or a conductive via plug) of the BEOL structure 50. In some embodiments, the first upper contact 42_1 may contact the first upper source/drain region 26U_1, and the second upper contact 42_2 may contact the second upper source/drain region 26U_2.

The BEOL structure 50 may include conductive wires (e.g., metal wires) stacked in the third direction Z, and conductive via plugs (e.g., metal via plugs), each of which may electrically connect two conductive wires that are spaced apart from each other in the third direction Z.

Each of the inter-gate insulator 20, the first insulating layer 31 and the second insulating layer 41 may include, for example, silicon oxide, silicon oxynitride, silicon nitride, silicon carbonitride and/or a low-k material.

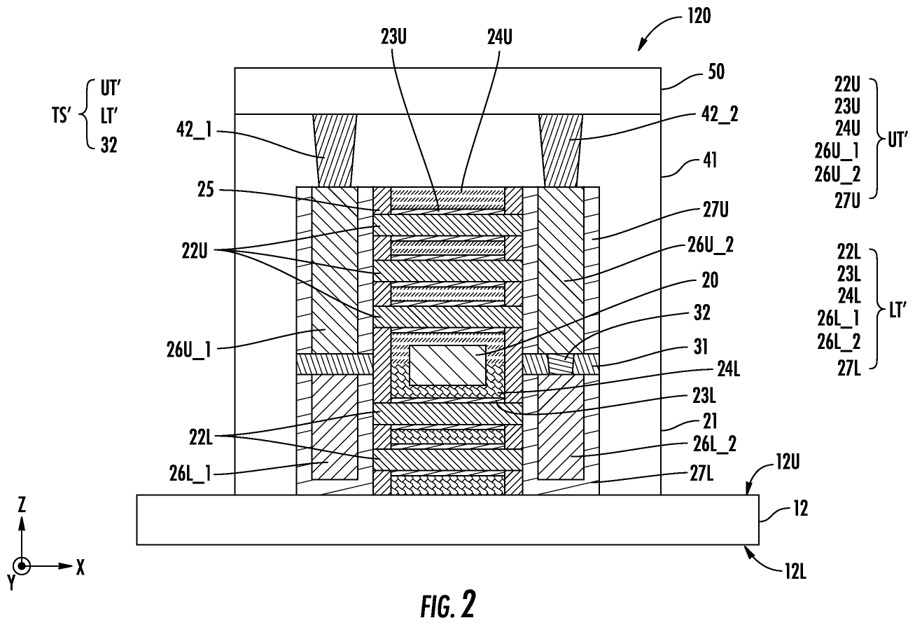

FIG. 2 is a cross-sectional view of a second integrated circuit device 120 according to some embodiments. The second integrated circuit device 120 is similar to the first integrated circuit device 110. The second integrated circuit device 120 may be different from the first integrated circuit device 110 in that a lower transistor LT′ of a transistor stack TS' additionally includes a lower interface layer 27L, and an upper transistor UT′ additionally includes an upper interface layer 27U. The lower interface layer 27L may reduce the Schottky barrier height of the first and second lower source/drain regions 26L_1 and 26L_2, and the upper interface layer 27U may reduce the Schottky barrier height of the first and second upper source/drain regions 26U_1 and 26U_2.

The lower interface layer 27L may be provided between the insulating spacer 25 and one of the first and second lower source/drain regions 26L_1 and 26L_2, and the lower channel region 22L may contact the lower interface layer 27L. Although FIG. 2 shows that lower portions of the lower interface layer 27L separate the substrate 12 from the first and second lower source/drain regions 26L_1 and 26L_2, in some embodiments, the substrate 12 may contact the first and second lower source/drain regions 26L_1 and 26L_2. When the lower transistor LT′ includes multiple lower channel regions 22L, all the lower channel regions 22L may contact the lower interface layer 27L.

The upper interface layer 27U may be provided between the insulating spacer 25 and one of the first and second upper source/drain regions 26U_1 and 26U_2, and the upper channel region 22U may contact the upper interface layer 27U. When the upper transistor UT′ includes multiple upper channel regions 22U, all the upper channel regions 22U may contact the upper interface layer 27U. Each of the lower interface layer 27L and the upper interface layer 27U may include, for example, semiconductor material(s) (e.g., Si, Ge, SiGe, GaP, GaAs, SiC, SiGeC and/or InP). In some embodiments, each of the lower interface layer 27L and the upper interface layer 27U may be a silicon layer or a silicon germanium layer. The lower interface layer 27L and the upper interface layer 27U may include the same material(s) or different materials. In some embodiments, the lower interface layer 27L and the upper interface layer 27U may include dopants (e.g., boron, aluminum, gallium, indium, phosphorus, arsenic, antimony, bismuth and/or lithium). For example, a dopant concentration of each of the lower interface layer 27L and the upper interface layer 27U may be in a range of from 1×10⁵ to 1×10²⁰ atoms/cm³. In some embodiments, the dopant concentration may be in a range of from 1×10⁵ to 1×10¹⁰ atoms/cm³ from 1×10¹⁰ to 1×10¹⁵ atoms/cm³ or from 1×10¹⁵ to 1×10²⁰ atoms/cm³.

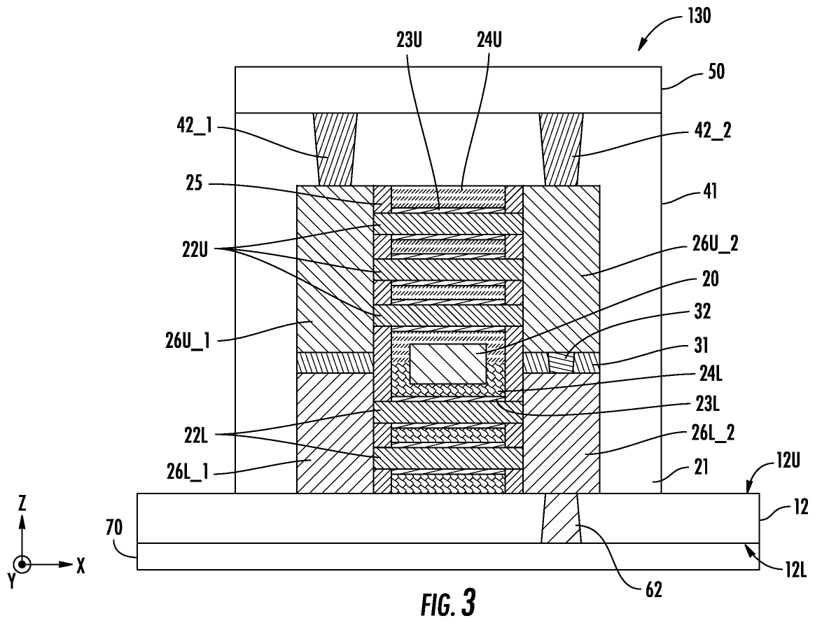

FIG. 3 is a cross-sectional view of a third integrated circuit device 130 according to some embodiments. The third integrated circuit device 130 is similar to the first integrated circuit device 110. The third integrated circuit device 130 may differ from the first integrated circuit device 110 in that the third integrated circuit device 130 includes a lower contact 62 and a back side power distribution network (BSPDN) structure 70. The lower contact 62 may be in the substrate 12. In some embodiments, the lower contact 62 may extend through the substrate 12 in the third direction Z, and the lower contact 62 may contact the second lower source/drain region 26L_2, as illustrated in FIG. 3. In some embodiments, a width of the lower contact 62 in a horizontal direction (e.g., the first direction X or the second direction Y) may increase with increasing distance from the second lower source/drain region 26L_2 in the third direction Z, as illustrated in FIG. 3.

The lower contact 62 may electrically connect the second lower source/drain region 26L_2 to a conductive element (e.g., a conductive wire or a conductive via plug) of the BSPDN structure 70. In some embodiments, the second lower source/drain region 26L_2 may be electrically connected to a power source with a predetermined voltage (e.g., a drain voltage or a source voltage). The BSPDN structure 70 may include multiple insulating layers stacked on the lower surface 12L of the substrate 12 and conductive elements provided in the insulating layers. The lower contact 62 may include a conductive layer that may include metal element(s) (e.g., W, Al, Cu, Mo and/or Ru).

Although not illustrated in FIG. 3, the third integrated circuit device 130 may additionally include the lower interface layer 27L and/or the upper interface layer 27U, which are illustrated in FIG. 2.

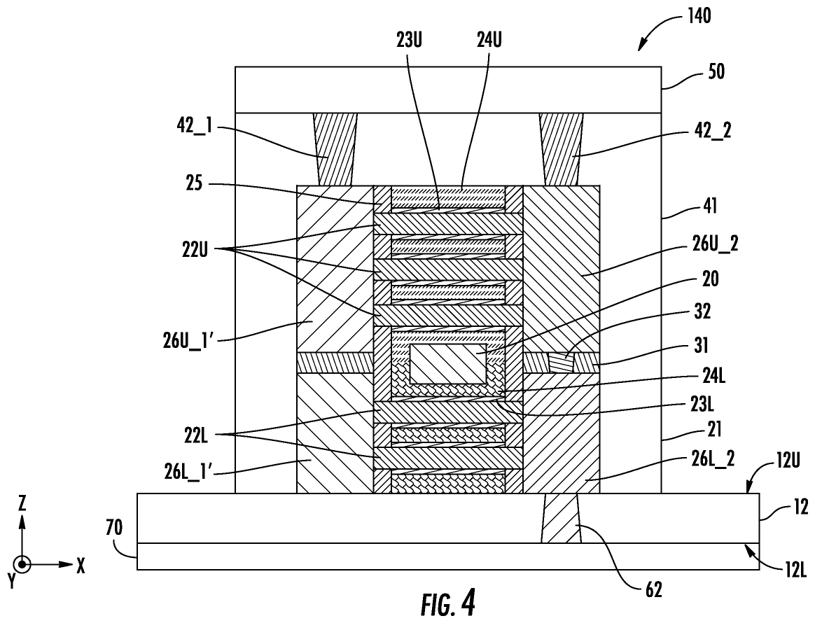

FIG. 4 is a cross-sectional view of a fourth integrated circuit device 140 according to some embodiments. The fourth integrated circuit device 140 is similar to the third integrated circuit device 130 with a primary difference being that the fourth integrated circuit device 140 includes a first lower source/drain region 26L_1′ and a first upper source/drain region 26U_1′, each of which includes a semiconductor layer (e.g., a silicon layer and/or a silicon germanium layer) and may additionally include dopants in the semiconductor layer. The first lower source/drain region 26L_1′ and the first upper source/drain region 26U_1′ may include the same material(s) or different material(s).

Although not illustrated in FIG. 4, the fourth integrated circuit device 140 may additionally include the lower interface layer 27L and/or the upper interface layer 27U, which are illustrated in FIG. 2. The lower interface layer 27L may be provided between the insulating spacer 25 (e.g., a lower portion of the insulating spacer 25) and the second lower source/drain region 26L_2, and the upper interface layer 27U may be provided between the insulating spacer 25 (e.g., an upper portion of the insulating spacer 25) and the second upper source/drain region 26U_2.

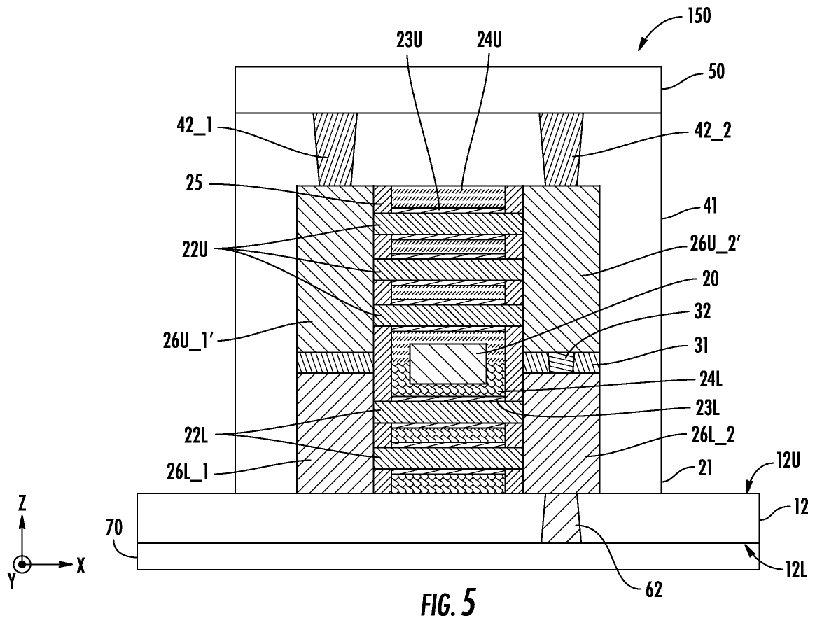

FIG. 5 is a cross-sectional view of a fifth integrated circuit device 150 according to some embodiments. The fifth integrated circuit device 150 is similar to the third integrated circuit device 130 with a primary difference being that the fifth integrated circuit device 150 includes first and second upper source/drain regions 26U_1′ and 26U_2′, each of which includes a semiconductor layer (e.g., a silicon layer and/or a silicon germanium layer) and may additionally include dopants in the semiconductor layer. The first and second upper source/drain regions 26U_1′ and 26U_2′ may include the same material(s) or different material(s).

Although not illustrated in FIG. 5, the fifth integrated circuit device 150 may additionally include the lower interface layer 27L that is illustrated in FIG. 2. The lower interface layer 27L may be provided between the insulating spacer 25 (e.g., a lower portion of the insulating spacer 25) and the first lower source/drain region 26L_1 and/or between the insulating spacer 25 and the second lower source/drain region 26L_2.

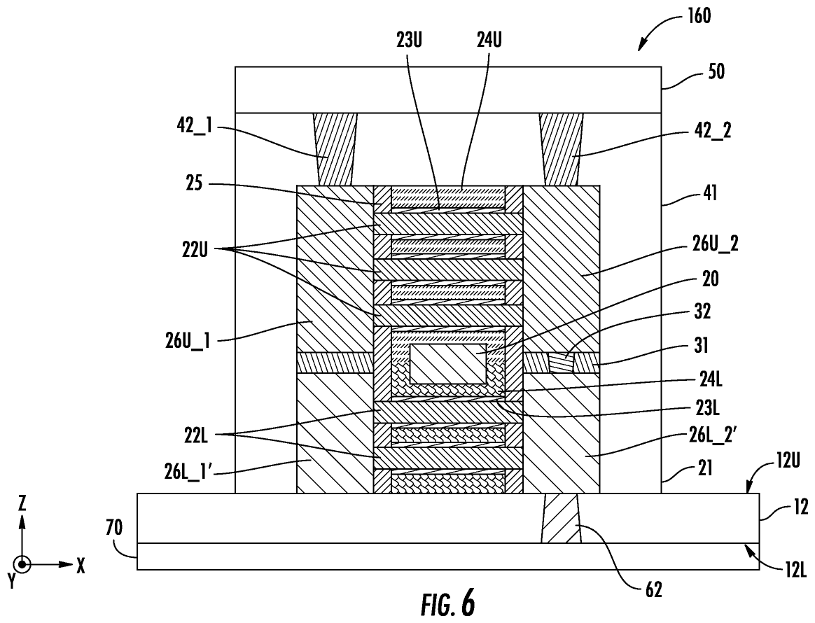

FIG. 6 is a cross-sectional view of a sixth integrated circuit device 160 according to some embodiments. The sixth integrated circuit device 160 is similar to the third integrated circuit device 130 with a primary difference being that the sixth integrated circuit device 160 includes first and second lower source/drain regions 26L_1′ and 26L_2′, each of which includes a semiconductor layer (e.g., a silicon layer and/or a silicon germanium layer) and may additionally include dopants in the semiconductor layer. The first and second lower source/drain regions 26L_1′ and 26L_2′ may include the same material(s) or different material(s).

Although not illustrated in FIG. 6, the sixth integrated circuit device 160 may additionally include the upper interface layer 27U that is illustrated in FIG. 2. The upper interface layer 27U may be provided between the insulating spacer 25 (e.g., an upper portion of the insulating spacer 25) and the first upper source/drain region 26U_1 and/or between the insulating spacer 25 and the second upper source/drain region 26U_2.

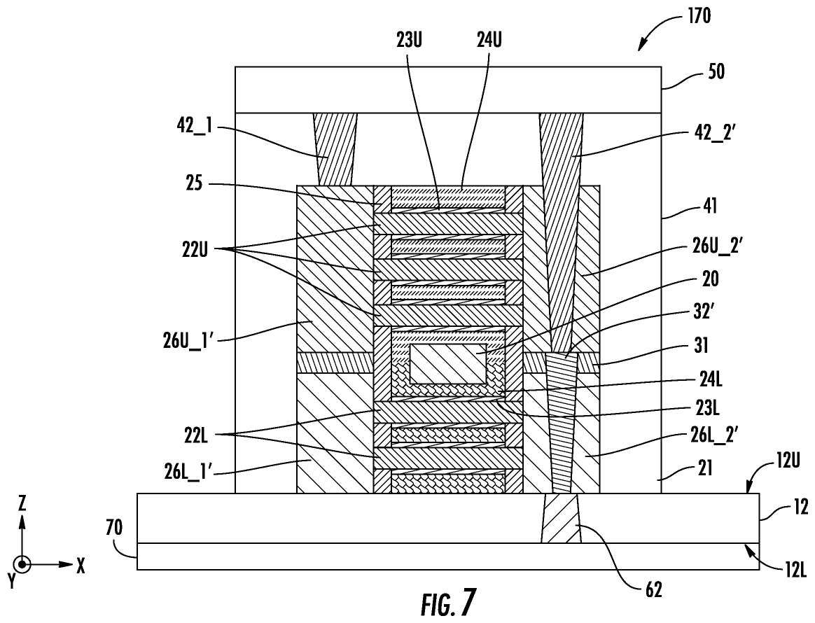

FIG. 7 is a cross-sectional view of a seventh integrated circuit device 170 according to some embodiments. The seventh integrated circuit device 170 is similar to the sixth integrated circuit device 160 with primary differences being that the seventh integrated circuit device 170 includes first and second upper source/drain regions 26U_1′ and 26U_2′, each of which includes a semiconductor layer (e.g., a silicon layer and/or a silicon germanium layer) and may additionally include dopants in the semiconductor layer, a metal interconnector 32′ extends through the second lower source/drain region 26L_2′ in the third direction Z, and a second upper contact 42_2′ extends through the second upper source/drain region 26U_2′ in the third direction Z.

In some embodiments, a width of the second upper contact 42_2′ in a horizontal direction (e.g., the first direction X or the second direction Y) may increase with increasing distance from the metal interconnector 32′ in the third direction Z, and a width of the metal interconnector 32′ in a horizontal direction (e.g., the first direction X or the second direction Y) may increase with increasing distance from the lower contact 62 in the third direction Z, as illustrated in FIG. 7. The upper contact 42_2′ may contact the metal interconnector 32′, and the metal interconnector 32′ may contact the lower contact 62. In some embodiments, the metal interconnector 32′ and the lower contact 62 may include different materials. For example, the metal interconnector 32′ may include molybdenum, and the lower contact 62 may include tungsten.

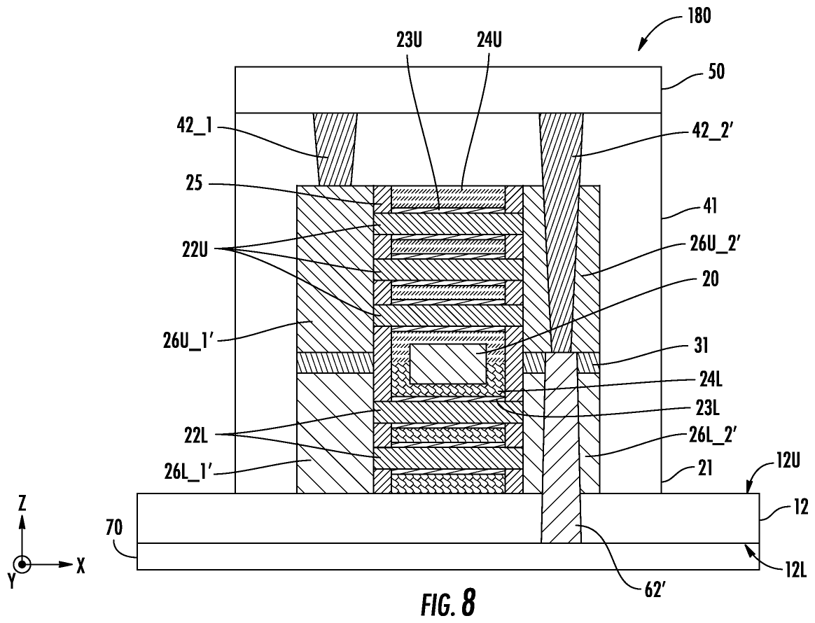

FIG. 8 is a cross-sectional view of an eighth integrated circuit device 180 according to some embodiments. The eighth integrated circuit device 180 is similar to the seventh integrated circuit device 170 with primary differences being that the eighth integrated circuit device 180 includes a lower contact 62′ that extends through the second lower source/drain region 26L_2′ in the third direction Z, and the metal interconnector 32′ is omitted. In some embodiments, a width of the lower contact 62′ in the first direction X may increase with increasing distance from the upper contact 42_2′.

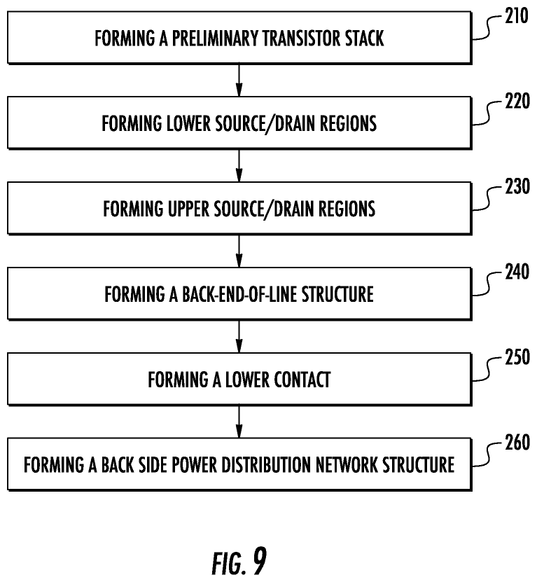

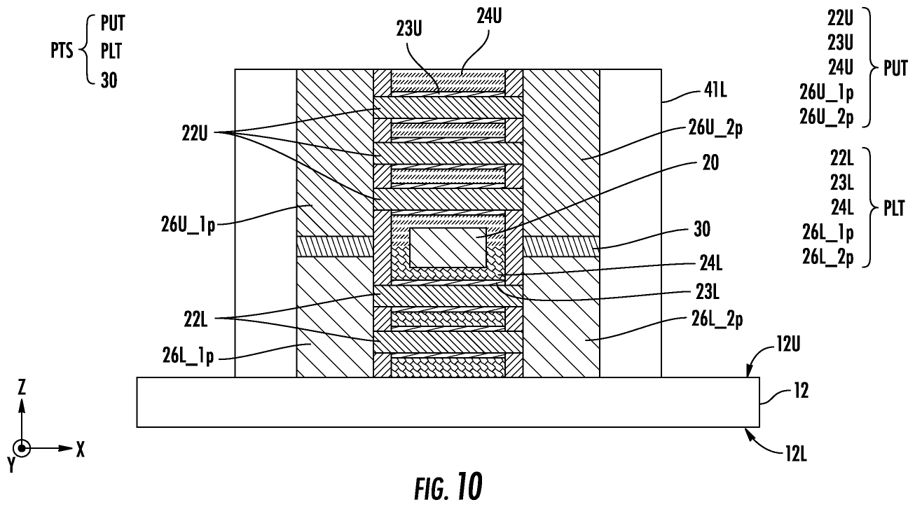

FIG. 9 is a flow chart of methods of forming the third integrated circuit device 130 according to some embodiments, and FIGS. 10 through 15 are cross-sectional views illustrating those methods according to some embodiments.

Referring to FIGS. 9 and 10, the methods may include forming a preliminary transistor stack PTS on a substrate 12 (Block 210). The preliminary transistor stack PTS may include a preliminary lower transistor PLT, a preliminary upper transistor PUT and a third insulating layer 30. The preliminary lower transistor PLT and the preliminary upper transistor PUT may be stacked in the third direction Z, and the third insulating layer 30 may be provided between the preliminary lower transistor PLT and the preliminary upper transistor PUT. The third insulating layer 30 may include, for example, silicon oxide, silicon oxynitride, silicon nitride, silicon carbonitride and/or a low-k material.

The preliminary lower transistor PLT may include a lower channel region 22L, a lower gate insulator 23L, a lower gate electrode 24L and first and second preliminary lower source/drain regions 26L_1p and 26L_2p. Each of the first and second preliminary lower source/drain regions 26L_1p and 26L_2p may include a semiconductor layer (e.g., a silicon layer and/or a silicon germanium layer) and may additionally include dopants in the semiconductor layer. The first and second preliminary lower source/drain regions 26L_1p and 26L_2p may include the same material(s) or different materials.

The preliminary upper transistor PUT may include an upper channel region 22U, an upper gate insulator 23U, an upper gate electrode 24U and first and second preliminary upper source/drain regions 26U_1p and 26U_2p. Each of the first and second preliminary upper source/drain regions 26U_1p and 26U_2p may include a semiconductor layer (e.g., a silicon layer and/or a silicon germanium layer) and may additionally include dopants in the semiconductor layer. The first and second preliminary upper source/drain regions 26U_1p and 26U_2p may include the same material(s) or different materials. An inter-gate insulator 20 may be provided between the lower gate electrode 24L and the upper gate electrode 24U. A lower second insulating layer 41L may be provided on an upper surface 12U of the substrate 12, and the preliminary transistor stack PTS may be provided in the lower second insulating layer 41L.

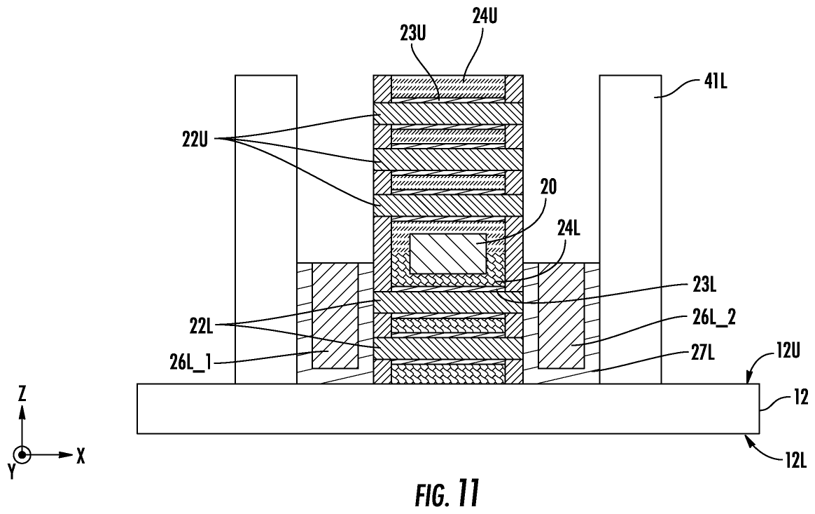

Referring to FIGS. 9 and 11, lower source/drain regions (i.e., first and second lower source/drain regions 26L_1 and 26L_2) may be formed (Block 220). In some embodiments, the first and second preliminary upper source/drain regions 26U_1p and 26U_2p and the third insulating layer 30 may be removed, and then the first and second preliminary lower source/drain regions 26L_1p and 26L_2p may be replaced with first and second lower source/drain regions 26L_1 and 26L_2, respectively. Before forming the first and second lower source/drain regions 26L_1 and 26L_2, a lower interface layer 27L may be formed.

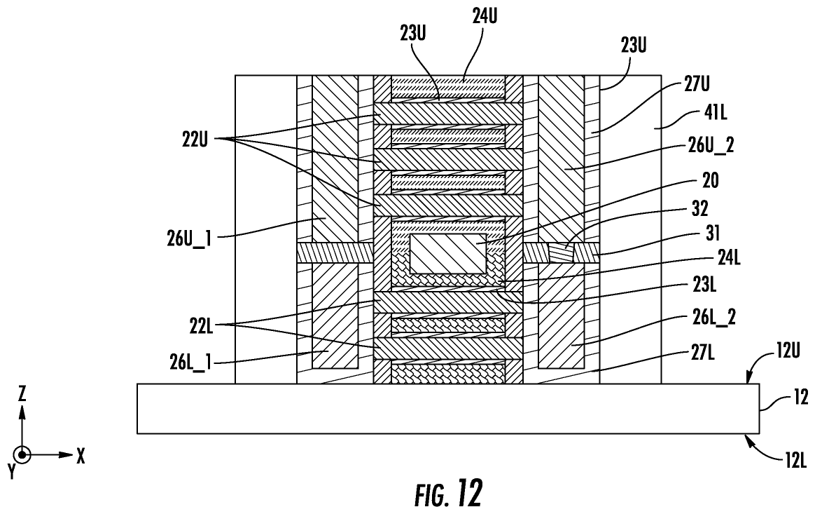

Referring to FIGS. 9 and 12, upper source/drain regions (i.e., first and second upper source/drain regions 26U_1 and 26U_2) may be formed (Block 230). In some embodiments, an upper interface layer 27U may be formed before forming the first and second upper source/drain regions 26U_1 and 26U_2. In some embodiments, a first insulating layer 31 may be formed on the first and second lower source/drain regions 26L_1 and 26L_2, and a metal interconnector 32 may be formed in the first insulating layer 31 before forming the first and second upper source/drain regions 26U_1 and 26U_2.

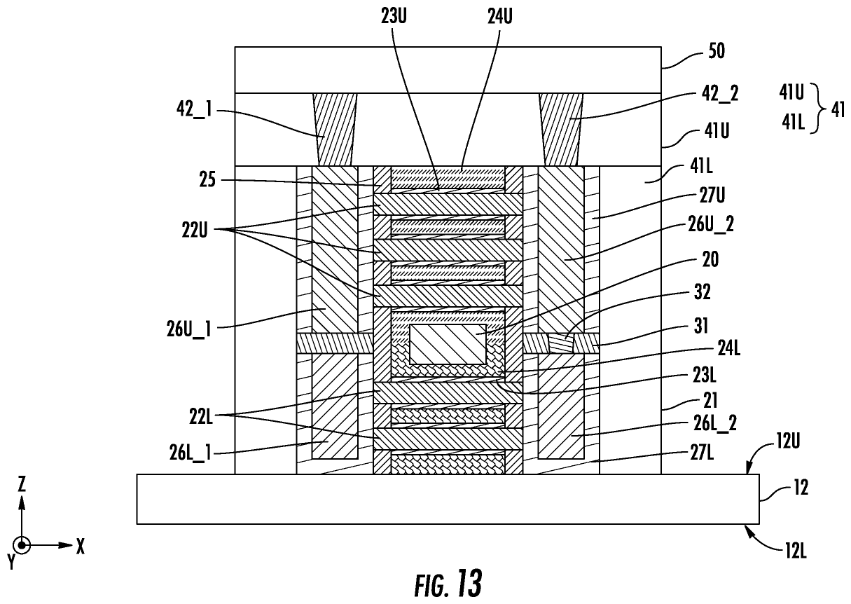

Referring to FIGS. 9 and 13, a BEOL structure 50 may be formed (Block 240) after forming an upper second insulating layer 41U and first and second upper contacts 42_1 and 42_2. The lower second insulating layer 41L and the upper second insulating layer 41U may be collectively referred to as a second insulating layer 41.

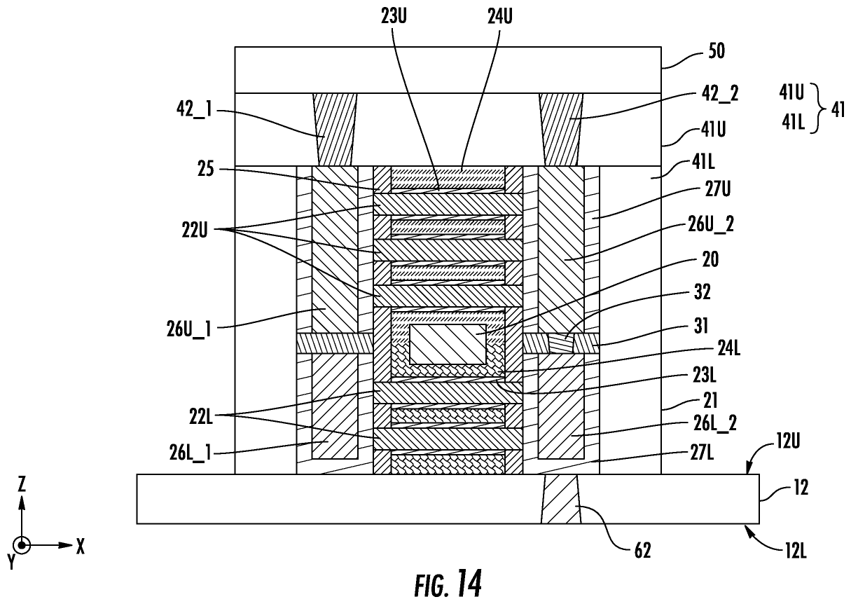

Referring to FIGS. 9 and 14, a lower contact 62 may be formed (Block 250) in the substrate 12. For example, an etch process may be performed on a lower surface 12L of the substrate 12 to form an opening in the substrate 12, and the lower contact 62 may be formed in the opening formed in the substrate 12. In some embodiments, before forming the lower contact 62, a process (e.g., a grinding process and/or an etch process) may be performed on the lower surface 12L of the substrate 12 to reduce a thickness of the substrate 12.

Referring to FIGS. 9 and 15, a BSPDN structure 70 may be formed (Block 260) on the lower surface 12L of the substrate 12. In some embodiments, the BSPDN structure 70 may contact the lower contact 62.

It will be understood that the first, second, and fourth to eighth integrated circuit devices 110, 120, 140, 150, 160, 170 and 180 can be formed by methods similar to those described with reference to FIGS. 9-15 with appropriate modification thereto.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present invention to those skilled in the art. In the drawings, the sizes and relative sizes of layers and regions may be exaggerated for clarity. Like reference numbers refer to like elements throughout.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a substrate; and
a transistor stack on the substrate, the transistor stack comprising a first transistor and a second transistor stacked in a first direction,
wherein the first transistor comprises first and second source/drain regions and a first channel region between the first and second source/drain regions, and the first source/drain region comprises a first metal layer,
the second transistor comprises third and fourth source/drain regions and a second channel region between the third and fourth source/drain regions, and the first and third source/drain regions overlap each other in the first direction, and
the transistor stack further comprises a metal interconnector contacting the third source/drain region and the first metal layer of the first source/drain region.

2. The integrated circuit device of claim 1, wherein the first metal layer of the first source/drain region contacts the first channel region.

3. The integrated circuit device of claim 2, wherein the first channel region comprises a plurality of first channel regions stacked in the first direction, wherein the first direction is a vertical direction, and
the first metal layer of the first source/drain region contacts the plurality of first channel regions.

4. The integrated circuit device of claim 1, wherein the first transistor further comprises:
a first gate structure between the first and second source/drain regions;
an insulating spacer between the first gate structure and the first source/drain region; and
an interface layer between the insulating spacer and the first source/drain region, opposing side surfaces of the interface layer contacting the insulating spacer and the first source/drain region, respectively,
wherein the first channel region contacts the interface layer and comprises a portion that is in the insulating spacer.

5. The integrated circuit device of claim 4, wherein the first channel region comprises a plurality of first channel regions stacked in the first direction, and
each of the plurality of first channel regions contacts the interface layer and comprises a portion that is in the insulating spacer.

6. The integrated circuit device of claim 4, wherein the interface layer comprises a semiconductor layer.

7. The integrated circuit device of claim 1, wherein the first transistor is between the substrate and the second transistor, and
the integrated circuit device further comprises a lower contact that is in the substrate and comprises a second metal layer contacting the first metal layer of the first source/drain region.

8. The integrated circuit device of claim 7, wherein a width of the lower contact in a horizontal direction increases with increasing distance from the first source/drain region.

9. The integrated circuit device of claim 1, wherein the second transistor is between the substrate and the first transistor, and
the integrated circuit device further comprises:
an insulating layer on the first source/drain region; and
an upper contact that is in the insulating layer and comprises a second metal layer contacting the first metal layer of the first source/drain region.

10. The integrated circuit device of claim 1, wherein the third source/drain region comprises a second metal layer contacting the metal interconnector, and
the first and second metal layers and the metal interconnector comprise the same material.

11. An integrated circuit device comprising:
a substrate;
an upper transistor on the substrate, wherein the upper transistor comprises upper source/drain regions and an upper channel region between the upper source/drain regions;
a lower transistor between the substrate and the upper transistor, wherein the lower transistor comprises lower source/drain regions and a lower channel region between the lower source/drain regions, and one of the lower source/drain regions comprises a first metal layer; and
a lower contact that is in the substrate and comprises a second metal layer contacting the first metal layer of the one of the lower source/drain regions.

12. The integrated circuit device of claim 11, wherein the lower channel region contacts the first metal layer of the one of the lower source/drain regions.

13. The integrated circuit device of claim 11, wherein the lower transistor further comprises:
a lower gate structure between the lower source/drain regions;
an insulating spacer between the lower gate structure and the one of the lower source/drain regions; and
an interface layer between the insulating spacer and the one of the lower source/drain regions, opposing side surfaces of the interface layer contacting the insulating spacer and the one of the lower source/drain regions, respectively,
wherein the lower channel region contacts the interface layer and comprises a portion that is in the insulating spacer.

14. The integrated circuit device of claim 13, wherein the lower transistor and the upper transistor are stacked in a first direction,
the lower channel region comprises a plurality of lower channel regions stacked in the first direction, and
each of the plurality of lower channel regions contacts the interface layer and comprises a portion that is in the insulating spacer.

15. The integrated circuit device of claim 14, wherein the interface layer comprises a semiconductor layer.

16. The integrated circuit device of claim 11, wherein the lower transistor and the upper transistor are stacked in a first direction,
one of the upper source/drain regions overlaps the one of the lower source/drain regions in the first direction, and the one of the upper source/drain regions comprises a third metal layer, and
the integrated circuit device further comprises a metal interconnector contacting the first metal layer of the one of the lower source/drain regions and the third metal layer of the one of the upper source/drain regions.

17. The integrated circuit device of claim 11, wherein the lower transistor and the upper transistor are stacked in a first direction, and
a width of the lower contact in a horizontal direction increases with increasing distance from the one of the lower source/drain regions, and the horizontal direction is perpendicular to the first direction.

18. A method of forming an integrated circuit device, the method comprising:
forming a preliminary transistor stack on a substrate, the preliminary transistor stack comprising an upper channel region and a lower channel region that is between the substrate and the upper channel region;
forming first and second lower source/drain regions that respectively contact opposing side surfaces of the lower channel region and comprise a first semiconductor material;
forming first and second upper source/drain regions that respectively contact opposing side surfaces of the upper channel region and comprise a second semiconductor material; and
replacing at least one of the first semiconductor material of the first lower source/drain region and the second semiconductor material of the first upper source/drain region with a metal layer.

19. The method of claim 18, further comprising forming a metal interconnector,
wherein the lower channel region and the upper channel region are stacked in a first direction, and the first upper source/drain region overlaps the first lower source/drain region in the first direction, and
the metal interconnector electrically connects the first lower source/drain region to the first upper source/drain region and contacts the metal layer.

20. The method of claim 18, wherein the first semiconductor material of the first lower source/drain region is replaced with the metal layer, and
the method further comprises forming a lower contact that is in the substrate and contacts the metal layer of the first lower source/drain region.
